(19) United States
(12) Patent Application Publication
(10) Pub. No.: US 2024/0393694 A1
(43) Pub. Date: Nov. 28, 2024

(54) METAL CONTAINING PHOTORESIST DEVELOPER COMPOSITION, AND METHOD OF FORMING PATTERNS INCLUDING STEP OF DEVELOPING USING THE COMPOSITION

(71) Applicant: SAMSUNG SDI CO., LTD., Yongin-si (KR)

(72) Inventors: Hyungrang MOON, Suwon-si (KR); Jongpil HO, Suwon-si (KR); Taeho KIM, Suwon-si (KR); Seung HAN, Suwon-si (KR); Gyeonghun PARK, Suwon-si (KR); Myoungsoo SONG, Suwon-si (KR); Taeksoo KWAK, Suwon-si (KR); Si-Kyun PARK, Suwon-si (KR); Jin-Hee BAE, Suwon-si (KR); Minsoo KIM, Suwon-si (KR)

(21) Appl. No.: 18/658,892

(22) Filed: May 8, 2024

(30) Foreign Application Priority Data
May 26, 2023 (KR) 10-2023-0068547

(51) Int. Cl. G03F 7/16

(52) U.S. Cl. CPC G03F 7/168

(57) ABSTRACT

A metal-containing photoresist developer composition includes an organic solvent, and a sulfonimide-based compound. A method of forming patterns utilizing the developer composition includes: coating a metal-containing resist composition on a substrate; coating a composition for removing edge beads from a metal-containing resist along an edge of the substrate; drying and heating the resultant to form a metal-containing resist layer on the substrate; exposing the metal-containing resist layer; and coating the metal-containing photoresist developer composition and developing the metal-containing photoresist developer composition.

### CROSS-REFERENCE TO RELATED APPLICATION

The present application claims priority to and the benefit of Korean Patent Application No. 10-2023-0068547, filed on May 26, 2023, in the Korean Intellectual Property Office, the entire disclosure of which is incorporated herein by reference.

### BACKGROUND DISCLOSURE

### 1. Field Disclosure

One or more aspects of embodiments of this disclosure are directed toward a metal-containing photoresist developer composition and a method of forming patterns including a developing step using the same.

### 2. Description of the Related Art

In recent years, a semiconductor industry has seen a continuous reduction of critical dimensions, and this dimensional reduction requires (or calls for) new types (or kinds) of high-performance photoresist materials and a patterning method that can satisfy a demand (or desire) for processing and patterning materials with increasingly smaller features.

Related art chemically amplified (CA) photoresists are designed to secure relatively high sensitivity, but because an elemental makeup of the CA photoresist (for example, of smaller quantities of O, F, S, and/or C) may lower absorbance at a wavelength of about 13.5 nm, as a result, sensitivity may be reduced and the photoresists may suffer more difficulties partially under the EUV (Extreme UltraViolet, wavelength of 13.5 nm) exposure. In addition, the CA photoresists may have difficulties due to roughness issues (e.g., undesirable or suitable roughness) in small feature sizes, and, as due partially to the nature of acid catalyst processes, LER (line edge roughness) experimentally may increase as a photospeed decreases. At least in part due to these drawbacks and problems of the CA photoresist a new type (or kind) of high-performance photoresists is required (or desired) in the semiconductor industry.

For example, it is necessary (or desired) to develop a photoresist capable of securing excellent or suitable etching resistance and resolution and simultaneously (or concurrently), improving sensitivity and enhancing CD (critical dimension) uniformity and LER (line edge roughness) characteristics in the photolithography process.

### SUMMARY DISCLOSURE

One or more aspects of embodiments of the present disclosure provide a metal-containing photoresist developer composition.

One or more aspects of embodiments of the present disclosure provide a method of forming patterns including a developing step using the composition.

A metal-containing photoresist developer composition according to some embodiments includes an organic solvent, and a sulfonimide-based compound.

The sulfonimide-based compound may be at least one selected from among the compounds represented by Chemical Formula 1 and Chemical Formula 2.

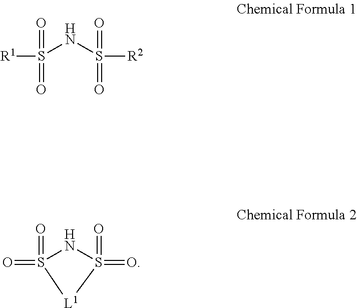

In Chemical Formula 1 and Chemical Formula 2,

R¹ and R² are each independently fluorine, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C3 to C20 cycloalkynyl group, a substituted or unsubstituted C6 to C20 aryl group, a substituted or unsubstituted C1 to C20 heteroaryl group, or a combination thereof, and

L¹ is a substituted or unsubstituted C1 to C10 alkylene group, a substituted or unsubstituted C3 to C20 cycloalkylene group, a substituted or unsubstituted C6 to C20 arylene group, a substituted or unsubstituted C1 to C20 heteroarylene group, or a combination thereof.

The sulfonimide-based compound may be at least one selected from among the compounds listed in Group I.

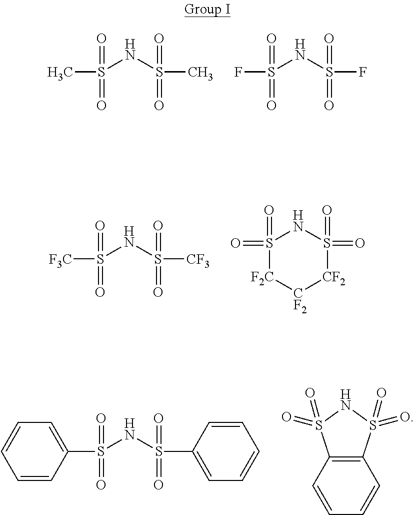

A pKa of the sulfonimide-based compound may be less than or equal to about 5.

The metal-containing photoresist developer composition according to some embodiments may include about 50 to about 99.99 wt % of the organic solvent; and about 0.01 to about 50 wt % of the sulfonimide-based compound.

A metal compound included in the metal-containing photoresist may be at least one selected from among an organooxy group-containing tin compound and an organocarbonyloxy group-containing tin compound.

The metal-containing photoresist may include a metal compound represented by Chemical Formula 3 or a condensation thereof:

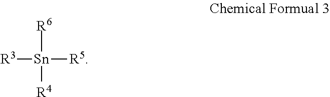

In Chemical Formula 3,
R³ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and -L^{a}-O—R^{a} (wherein L^{a} is a substituted or unsubstituted C1 to C20 alkylene group and R^{a} is a substituted or unsubstituted C1 to C20 alkyl group),
R⁴ to R⁶ may each independently be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, —OR^{b} and —OC(═O)R^{c},
R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
at least one selected from among R⁴ to R⁶ may each independently be selected from among-OR^{b} and —OC(═O)R^{c}.

A method of forming patterns according to some embodiments includes coating a metal-containing photoresist composition on a substrate, coating the composition for removing edge beads from the metal-containing photoresist along the edge of the substrate, drying and heating the resultant to form a metal-containing photoresist layer on the substrate, exposing the metal-containing photoresist layer, and coating the metal-containing photoresist developer composition of the present embodiments and developing the same.

The method of forming patterns according to some embodiments may minimize or reduce residual films, scums, and/or defects present in the metal-containing photoresist layer after the exposure process and may enable easy or suitable development, thereby realizing excellent or improved contrast characteristics.

### BRIEF DESCRIPTION OF THE DRAWINGS

These and/or other aspects will become apparent and more readily appreciated from the following description of the embodiments, taken in conjunction with the accompanying drawings in which:

FIGS. 1-3 are cross-sectional views illustrating a process sequence of a method of forming patterns according to one or more embodiments of the present disclosure.

### DETAILED DESCRIPTION

Hereinafter, embodiments of the present disclosure will be described in more detail with reference to the accompanying drawings. In the following description of the present disclosure, the well-known functions or constructions will not be described for clarity of the present disclosure.

In order to clearly illustrate the present disclosure, certain descriptions and relationships that should be understood by those of ordinary skill in the art are not provided, and throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto.

In the drawings, the thickness of layers, films, panels, regions, etc., are exaggerated for clarity. In the drawings, the thickness of a part of layers and/or regions, etc., is exaggerated for clarity. It will be understood that when an element such as a layer, film, region, or substrate is referred to as being “on” another element, it can be directly on the other element (e.g., without any intervening elements therebetween) or intervening elements may also be present.

It will be understood that, although the terms first, second, etc. may be used herein to describe various elements, these elements should not be limited by these terms. These terms are only used to distinguish one element from another element. Thus, a first element could be termed a second element without departing from the teachings of the present disclosure. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, “substituted” refers to replacement of a hydrogen atom by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” means that a hydrogen atom remains as a hydrogen atom without being replaced by another substituent.

In the present disclosure, the term “alkyl group” may refer to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C5 alkyl group means that the alkyl chain contains 1 to 5 carbon atoms, and may be selected from among methyl, ethyl, propyl, iso-propyl, n-butyl, iso-butyl, sec-butyl, and t-butyl.

Examples of the alkyl group may include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, etc.

In the present disclosure, the term “cycloalkyl group” may refer to a monovalent cyclic aliphatic hydrocarbon group unless otherwise defined.

In the present disclosure, the term “alkenyl group”, unless otherwise defined, may refer to a linear or branched aliphatic hydrocarbon group, and may refer to an aliphatic unsaturated alkenyl group containing one or more carbon-carbon double bonds.

In the present disclosure, the term “alkynyl group”, unless otherwise defined, may refer to a linear or branched aliphatic hydrocarbon group, and may refer to an unsaturated alkynyl group containing one or more carbon-carbon triple bonds.

In the present disclosure, “aryl group” may refer to a substituent in which all elements (or atoms) of a cyclic substituent or group have p-orbitals, and these p-orbitals form a conjugate. It may include monocyclic or polycyclic of fused ring (e.g., rings that share adjacent pairs of carbon atoms) functional groups.

Hereinafter, a metal-containing photoresist developer composition according to some embodiments is described.

The metal-containing photoresist developer composition according to some embodiments of the present disclosure includes an organic solvent, and a sulfonimide-based compound.

If the metal-containing photoresist developer composition including a sulfonimide-based compound is applied (e.g., is utilized) for development, because an imide group of the sulfonimide-based compound forms a chelate bond to a resist containing a metal (e.g., to the metal in the resist), excellent or improved contrast characteristics may be realized by minimizing or reducing residual films/scums/defects on the metal-containing photoresist layer after the exposure process.

A suitable developer for the metal-containing photoresist layer (e.g., in related art) may include carboxylic acid, which is a relatively weak acid, and thus may lacks suitable or desired cleaning power for the metal-containing photoresist layer and thus may not fully or suitably satisfy a demand for processing and patterning smaller features according to pattern refinement.

By way of contrast, the metal-containing photoresist developer composition according to some embodiments of the present disclosure includes the sulfonimide-based compound, which is a relatively stronger acidic material than the carboxylic acid, and thus may secure improved cleaning power to sufficiently or suitably dissolve a non-exposed region, thereby significantly minimizing or reducing residual films, scums, and/or defects and thus lowering a pattern defect rate.

For example, the pKa of the sulfonimide-based compound may be −20≤pKa≤5, for example −15≤pKa≤5.

If the pKa of the sulfonimide-based compound is within the above range, the film removal ability can be further improved.

The sulfonimide-based compound may be at least one selected from among the compounds represented by Chemical Formula 1 and Chemical Formula 2.

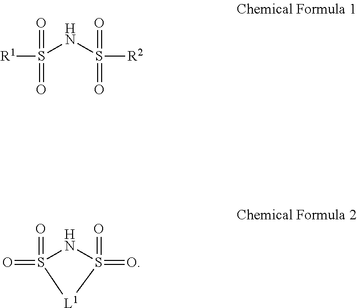

In Chemical Formula 1 and Chemical Formula 2,
R¹ and R² may each independently be fluorine, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C3 to C20 cycloalkynyl group, a substituted or unsubstituted C6 to C20 aryl group, a substituted or unsubstituted C1 to C20 heteroaryl group, or a combination thereof, and
L¹ may be a substituted or unsubstituted C1 to C10 alkylene group, a substituted or unsubstituted C3 to C20 cycloalkylene group, a substituted or unsubstituted C6 to C20 arylene group, a substituted or unsubstituted C1 to C20 heteroarylene group, or a combination thereof.

For example, R¹ and R² may each independently be fluorine, a C1 to C20 alkyl group unsubstituted or substituted with at least one fluorine, a C2 to C20 alkenyl group unsubstituted or substituted with at least one fluorine, a C2 to C20 alkynyl group unsubstituted or substituted with at least one fluorine, a C3 to C20 cycloalkyl group unsubstituted or substituted with at least one fluorine, a C3 to C20 cycloalkenyl group unsubstituted or substituted with at least one fluorine, a C3 to C20 cycloalkynyl group unsubstituted or substituted with at least one fluorine, a C6 to C20 aryl group unsubstituted or substituted with at least one fluorine, a C1 to C20 heteroaryl group unsubstituted or substituted with at least one fluorine, or a combination thereof, and
L¹ may be a C1 to C10 alkylene group unsubstituted or substituted with at least one fluorine, a C3 to C20 cycloalkylene group unsubstituted or substituted with at least one fluorine, a C6 to C20 arylene group unsubstituted or substituted with at least one fluorine, a C1 to C20 heteroarylene group unsubstituted or substituted with at least one fluorine, or a combination thereof.

In one or more embodiments, R¹ and R² may each independently be fluorine, an unsubstituted C1 to C20 alkyl group, a C1 to C20 alkyl group substituted with at least one fluorine, an unsubstituted C3 to C20 cycloalkyl group, a C3 to C20 cycloalkyl group, substituted with at least one fluorine, an unsubstituted C1 to C20 cycloalkyl group, a C1 to C20 cycloalkyl group substituted with at least one fluorine, an unsubstituted C6 to C20 aryl group, a C6 to C20 aryl group substituted with at least one fluorine, or a combination thereof,
L¹ may be a C1 to C5 alkylene group unsubstituted or substituted with at least one fluorine, a C3 to C10 cycloalkylene group unsubstituted or substituted with at least one fluorine, a C6 to C20 arylene group unsubstituted or substituted with at least one fluorine, or a combination thereof.

In some embodiments, R¹ and R² may each independently be fluorine, a C1 to C10 alkyl group unsubstituted or substituted with at least one fluorine, a C6 to C20 aryl group unsubstituted or substituted with at least one fluorine, or a combination thereof, and
L¹ may be a C1 to C3 alkylene group unsubstituted or substituted with at least one fluorine.

For example, the sulfonimide-based compound may be at least one selected from among the compounds listed in Group I.

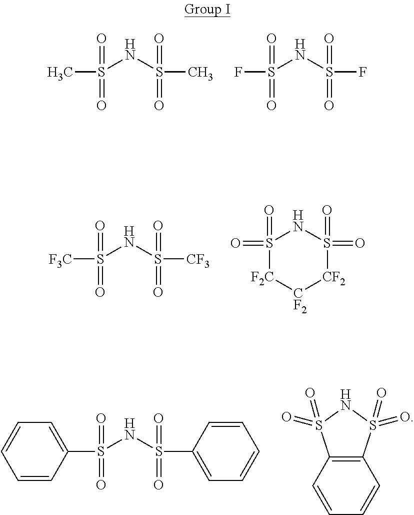

In some embodiments, the metal-containing photoresist developer composition may include about 50 wt % to about 99.99 wt % of the organic solvent and about 0.01 wt % to about 50 wt % of the sulfonimide-based compound.

Within any of the above ranges, the sulfonimide-based compound may be included in an amount of less than or equal to about 40 wt %, and for example, less than or equal to about 30 wt %, less than or equal to about 20 wt %, or less than or equal to about 10 wt %.

In some embodiments, the metal-containing photoresist developer composition may include the sulfonimide-based compound in an amount of about 0.01 to about 40 wt %, for example, about 0.01 to about 30 wt %, for example about 0.01 to about 20 wt %, for example about 0.01 to about 10 wt %.

Examples of the organic solvent included in the developer composition may include at least one selected from among ether, alcohol, glycol ether, aromatic hydrocarbon compounds, ketone, and ester, but are not limited thereto. For example, the organic solvent may include ethyleneglycolmonomethylether, ethyleneglycolmonoethylether, methylcellosolveacetate, ethylcellosolveacetate, diethyleneglycolmethylether, diethyleneglycolethylether, propyleneglycol, propyleneglycolmethylether (PGME), propyleneglycolmethyletheracetate (PGMEA), propyleneglycolethylether, propyleneglycolethyletheracetate, propyleneglycolpropyletheracetate, propyleneglycolbutylether, propyleneglycolbutyletheracetate, ethanol, propanol, isopropyl alcohol, isobutyl alcohol, 4-methyl-2-pentanol (or referred to as methyl isobutyl carbinol (MIBC)), hexanol, 1-methoxy-2-propanol, 1-ethoxy-2-propanol, ethyleneglycol, propyleneglycol, heptanone, propylenecarbonate, butylene carbonate, toluene, xylene, methylethylketone, cyclopentanone, cyclohexanone, 2-hydroxy ethyl propionate, 2-hydroxy-2-methyl ethyl propionate, ethoxy ethyl acetate, hydroxy ethyl acetate, 2-hydroxy-3-methylmethyl butanoate, 3-methoxy methyl propionate, 3-methoxy ethyl propionate, 3-ethoxy ethyl propionate, 3-ethoxy methyl propionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxyethoxy propionate, ethoxyethoxy propionate, or a combination thereof, but is not limited thereto.

The developer composition according to the present disclosure may be particularly effective or suitable in removing metal-containing resists, for example, undesirable metal residues, such as tin-based metal residues.

If the additives to be described in more detail herein below are included, the organic solvent may be included in a balance amount except for the components.

The developer composition may further include at least one additive selected from among a surfactant, a dispersant, a moisture absorbent, and a coupling agent.

The metal-containing resist composition may include a tin-based compound. For example, the tin-based compound may be at least one selected from among an organooxy group-containing tin compound and an organocarbonyloxy group-containing tin compound.

By way of example, the metal compound included in the metal-containing resist may be represented by Chemical Formula 3:

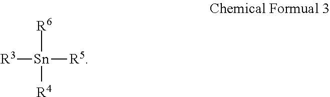

In Chemical Formula 3,
R³ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and -L^{a}-O—R^{a} (wherein L^{a} is a substituted or unsubstituted C1 to C20 alkylene group and R^{a} is a substituted or unsubstituted C1 to C20 alkyl group),
R⁴ to R⁶ may each independently be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, —OR^{b} and —OC(═O)R^{c},
R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
at least one selected from among R⁴ to R⁶ may each independently be selected from —OR^{b} and —OC(═O)R^{c}.

For example, R^{b} and Re may each independently be a substituted or unsubstituted C1 to C20 alkyl group.

According to some embodiments, a method of forming patterns includes a step (or act) of development using the metal-containing photoresist developer composition of the present embodiments. For example, the manufactured pattern may be a negative-type (or kind) photoresist pattern.

Hereinafter, a pattern forming method according to some embodiments will be described in more detail using the drawings as an example.

A method of forming patterns according to some embodiments includes coating a metal-containing resist composition on a substrate, coating the composition for removing edge beads from the metal-containing resist along the edge of the substrate, drying and heating the resultant to form a metal-containing resist layer on the substrate, exposing the metal-containing resist layer, and coating the developer composition according to the present embodiments and developing the same.

For example, the forming of patterns using the metal-containing resist composition may include coating a metal-containing resist composition on a substrate on which a thin film is formed by spin coating, slit coating, inkjet printing, etc., and drying the coated metal-containing resist composition to form a resist layer.

The metal-containing resist composition may include a tin-based compound, for example, the tin-based compound may include at least one selected from among an organooxy group-containing tin compound and an organocarbonyloxy group-containing tin compound.

Subsequently, the composition for removing edge beads from the metal-containing photoresist may be coated along the edge of the substrate.

For example, the composition for removing edge beads from the metal-containing resist may be applied in an appropriate or suitable amount along the edge of the substrate, and after the composition for removing the edge beads from the metal-containing resist is transferred, the substrate is spun at an appropriate or suitably set rate (e.g., 1,000 rpm or more) to remove beads on the edge of the substrate.

Next, a first heat treatment process of heating the substrate on which the metal-containing resist layer is formed is performed. The first heat treatment process may be performed at a temperature of about 80° C. to about 120° C. In this process, the solvent is evaporated and the metal-containing resist layer may be more firmly adhered to the substrate.

Then, the resist layer is selectively exposed utilizing a patterned mask.

For example, examples of light that may be used in the exposure process may include not only light having a wavelength such as i-line (wavelength 365 nm), KrF excimer laser (wavelength of 248 nm), and/or ArF excimer laser (wavelength of 193 nm), but also light having a high energy wavelength such as EUV (Extreme UltraViolet, wavelength of 13.5 nm), E-Beam (electron beam), etc.

For example, the light for exposure according to some embodiments may be short-wavelength light having a wavelength range of about 5 nm to about 150 nm, and light having a high energy wavelength such as EUV (Extreme UltraViolet, wavelength 13.5 nm), E-Beam (electron beam), etc.

In the step of forming the photoresist pattern, a negative-type (or kind) pattern may be formed.

The exposed region of the photoresist layer has a solubility different from that of the unexposed region of the photoresist layer as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist layer becomes difficult to be dissolved in a developer solution.

For example, the photoresist pattern corresponding to the negative-type tone image may be completed by dissolving and then removing the photoresist layer corresponding to the unexposed region using the photoresist developer composition according to the present embodiments.

According to one or more embodiments, the photoresist pattern formed by exposure to not only light having a short wavelength such as i-line (wavelength of 365 nm), KrF excimer laser (wavelength of 248 nm), and/or ArF excimer laser (wavelength of 193 nm), but also to light having high energy such as EUV (Extreme UltraViolet; wavelength of 13.5 nm), and/or an E-beam (electron beam), may have a thickness width (e.g., thickness and/or width) of about 5 nm to about 100 nm. For example, the photoresist pattern may be formed to have a thickness width (e.g., thickness and/or width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

The photoresist pattern may have a pitch having a half-pitch of less than or equal to about 50 nm, for example less than or equal to about 40 nm, for example less than or equal to about 30 nm, for example less than or equal to about 20 nm, for example less than or equal to about 15 nm, and a line width roughness (e.g., line edge roughness (LER)) of less than or equal to about 10 nm, less than or equal to about 5 nm, less than or equal to about 3 nm, or less than or equal to about 2 nm.

Hereinafter, a method of forming patterns is described in more detail with reference to the drawings.

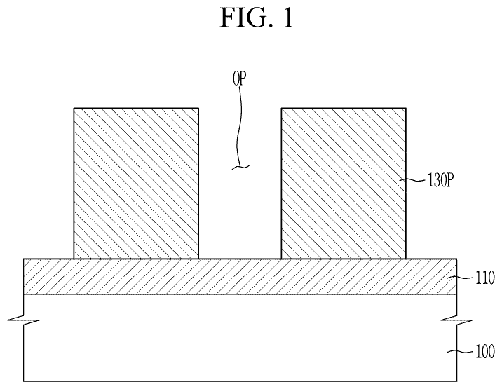

FIGS. 1 to 3 are cross-sectional views illustrating a process sequence in order to explain a method of forming patterns.

Referring to FIG. 1, the exposed photoresist layer is developed to form a photoresist pattern 130P.

In one or more embodiments, the exposed photoresist layer may be developed to remove an unexposed region of the photoresist layer, and the photoresist pattern 130P including (or corresponding to) the exposed region of the photoresist layer may be formed. The photoresist pattern 130P may include a plurality of openings OP.

In one or more embodiments, the development of the photoresist layer may be performed through an NTD (negative-tone development) process. Herein, the metal-containing photoresist developer composition according to some embodiments may be used as a developer composition.

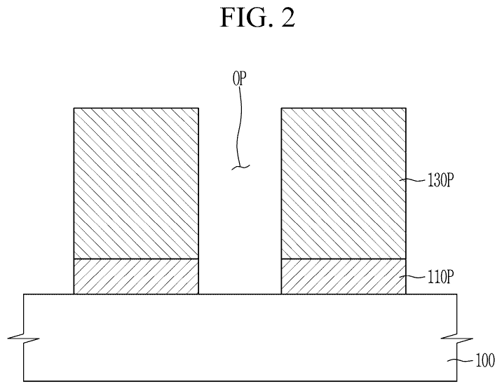

Referring to FIG. 2, the photoresist pattern 130P is used to process a feature layer 110 in the result of FIG. 1.

For example, the feature layer 110, may be processed through one or more suitable processes of etching a feature layer 110 exposed through the openings OP of the photoresist pattern 130P, injecting impurity ions into the feature layer 110, forming an additional film on the feature layer 110 through the openings OP, deforming a portion of the feature layer 110 through the openings OP, and/or the like. FIG. 2 illustrates an example process (e.g., method) of processing a feature pattern 110P by etching the feature layer 110 exposed through the openings OP.

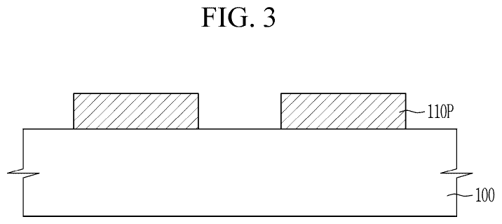

Referring to FIG. 3, the photoresist pattern 130P remaining on the feature pattern 110P is removed in the result of FIG. 2. In order to remove the photoresist pattern 130P, ashing and/or stripping processes may be utilized.

Hereinafter, the present disclosure will be described in more detail through examples relating to the preparation of the metal-containing photoresist developer composition according to the present embodiments. However, the technical features of the present disclosure are not limited by the following examples.

### Preparation of Metal-Containing Photoresist Developer Composition

A sulfonimide-based compound was mixed with an organic solvent in a PP (polypropylene) bottle according to each composition as shown in Table 1 and then, completely dissolved therein by shaking the bottle at room temperature (25° C.). Subsequently, the obtained solution was passed through a polytetrafluoroethylene (PTFE) filter with a pore size of 1 μm to prepare a developer composition.

TABLE 1

| | Developer composition | | | |
|---|---|---|---|---|
| | Organic solvent | sulfonimide-based compound | | |
| | (wt %) | Type (kind) | pKa | wt % |
| Example 1 | PGMEA (99.99) | Bis(trifluoromethane- | −10.4 | 0.01 |
| Example 2 | MIBC (99.0) | sulf onyl)imide | | 1 |
| Example 3 | PGMEA (99.99) | 1,1,2,2,3,3,- | −11.6 | 0.01 |
| Example 4 | PGME (99.0) | hexafluoropropane-1,3- | | 1 |
| | | disulfonimide | | |
| Example 5 | PGMEA (99.9) | Dibenzenesulfonimide | 2.85 | 0.1 |
| Example 6 | MIBC (95.0) | | | 10 |
| Example 7 | EL (99.9) | Imidodisulfurylfluoride | −3.66 | 0.1 |
| Example 8 | GBL (99.0) | | | 1 |
| Example 9 | PGMEA (99.9) | 1,2-Benzenedisulfonic | −0.83 | 0.1 |
| Example 10 | MIBC (95.0) | imide | | 5 |
| Example 11 | MIBC (99.5) | Dimethylsulfonic imide | 1.85 | 0.5 |
| Example 12 | GBL (92.0) | | | 8 |
| Comparative | PGMEA (100) | | — | — |
| Example 1 | | | | |
| Comparative | PGMEA (99.0) | Succimide | 9.5 | 1 |
| Example 2 | | | | |
| Comparative | PGME (90.0) | Maleimide | 10.0 | 10 |
| Example 3 | | | | |
| Comparative | GBL (90.0) | Phthalimide | 8.3 | 1 |
| Example 4 | | | | |

PGME: propylene glycol monomethyl ether
PGMEA: propylene glycol monomethyl ether acetate
MIBC: methyl isobutyl carbinol
EL: ethyl lactate
GBL: gamma-butyrolactone

### Preparation of Metal-Containing Photoresist Composition

An organometallic compound with a structural unit represented by Chemical Formula C was dissolved in 4-methyl-2-pentanol at a concentration of 1 wt % and then, filtered with a 0.1 μm PTFE syringe filter to prepare a metal-containing photoresist composition.

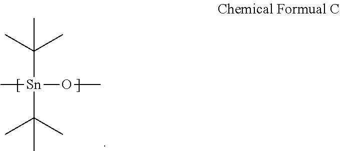

### Evaluation 1: Residual Film Thickness

1.0 mL of the organometallic compound-containing photoresist composition according to the preparation example was spin-coated on a 4-inch silicon wafer at 800 rpm for 30 seconds and then, allowed to stand for 20 seconds. Subsequently, after a heat treatment at 100° C. for 60 seconds and subsequently, at 180° C. for 60 seconds, 10 mL of each of the developer compositions according to Examples 1 to 12 and Comparative Examples 1 to 4 was spin-coated for 60 seconds and then, dried, while rotating at 1,500 rpm, and heat-treated at 200° C. for 60 seconds, and each film obtained therefrom was measured with respect to a thickness in an ellipsometry method to evaluate a remaining film thickness after the development process with reference to the following criteria. The results are shown in Table 2.

### Criteria for Evaluating Residual Film Thickness

If the residual film thickness is less than 1.0 nm: ∘
Residual film thickness 1.0 nm or more and less than 3 nm: Δ
For residual film thickness of 3 nm or more: X

### Evaluation 2: Defect Evaluation

The prepared organic metal-containing photoresist (PR) composition was spin-coated on an 8-inch wafer at 1,500 rpm for 30 seconds and heat-treated at 100° C. for 60 seconds to manufacture a coated wafer.

The coated wafer was exposed to light with 20 to 100 mJ in a 180 nm 1:1 line/space pattern by using a KrF scanner (PAS 5500/700D, ASML), heat-treated at 180° C. for 60 seconds, developed by applying each developer composition of Examples 1 to 12 and Comparative Examples 1 to 4, respectively, at a spin speed of 1500 rpm for 30 seconds, and cured at 240° C. for 60 seconds.

After the curing process, the obtained pattern wafer, on which the line/space CD pattern was formed, was transferred to a CD-SEM measurement equipment to obtain CD-SEM images.

Among the CD-SEM images, an image with a 180 nm space CD was selected and evaluated with respect to a defect (scum, bridge, pattern collapse) area ratio in the space portion by using an Macview (MounTech Co., Ltd.) program with reference to the following criteria, and the results are shown in Table 2.

### Detect Evaluation Criteria

A: No defects
B: Defect less than 10%
C: Defect 10% or more

TABLE 2

| | Evaluation of residual film | Defect |
|---|---|---|
| | thickness | evaluation |
| Example 1 | ◯ | A |
| Example 2 | ◯ | A |
| Example 3 | ◯ | A |
| Example 4 | ◯ | A |
| Example 5 | ◯ | A |
| Example 6 | ◯ | A |
| Example 7 | ◯ | A |
| Example 8 | ◯ | A |
| Example 9 | ◯ | A |
| Example 10 | ◯ | A |
| Example 11 | ◯ | A |
| Example 12 | ◯ | A |
| Comparative Example 1 | X | C |
| Comparative Example 2 | Δ | B |
| Comparative Example 3 | X | C |
| Comparative Example 4 | Δ | B |

Referring to Table 2, when each of the metal-containing photoresist developer compositions of Examples 1 to 12 was applied, compared with when each of the metal-containing photoresist developer compositions of Comparative Examples 1 to 4 was applied, excellent or improved capability of removing a metal-containing photoresist layer and excellent or improved pattern characteristics due to minimized or reduced defects were obtained.

Hereinbefore, certain embodiments of the present disclosure have been described and illustrated, however, it should be apparent to a person with ordinary skill in the art that the present disclosure is not limited to the embodiments as described, and may be variously suitably modified and transformed without departing from the spirit and scope of the present disclosure. Accordingly, the modified and/or transformed embodiments as such may not be understood separately from the technical ideas and aspects of the present disclosure, and the modified embodiments are within the scope of the claims of the present disclosure and their equivalents.

Description of Symbols

| | |
|---|---|
| 100: substrate | OP: opening |
| 110: feature layer | |
| 110P: feature pattern | 130P: photoresist pattern |

What is claimed is:

1. A metal-containing photoresist developer composition, comprising:
an organic solvent, and
a sulfonimide-based compound.

2. The metal-containing photoresist developer composition as claimed in claim 1, wherein
the sulfonimide-based compound is at least one selected from among compounds represented by Chemical Formula 1 and Chemical Formula 2: 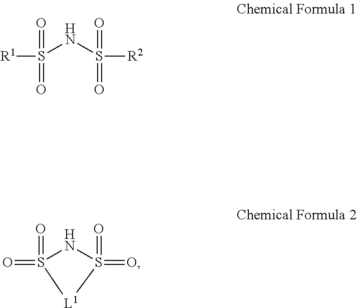
and
wherein, in Chemical Formula 1 and Chemical Formula 2,
R¹ and R² are each independently fluorine, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C3 to C20 cycloalkynyl group, a substituted or unsubstituted C6 to C20 aryl group, a substituted or unsubstituted C1 to C20 heteroaryl group, or a combination thereof, and
L¹ is a substituted or unsubstituted C1 to C10 alkylene group, a substituted or unsubstituted C3 to C20 cycloalkylene group, a substituted or unsubstituted C6 to C20 arylene group, a substituted or unsubstituted C1 to C20 heteroarylene group, or a combination thereof.

3. The metal-containing photoresist developer composition as claimed in claim 1, wherein
the sulfonimide-based compound is at least one selected from among compounds listed in Group I:

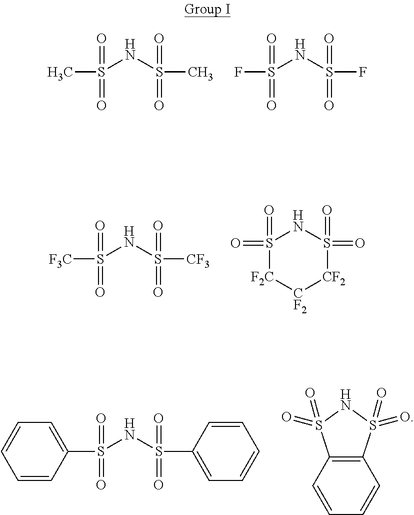

4. The metal-containing photoresist developer composition as claimed in claim 1, wherein
pKa of the sulfonimide-based compound is less than or equal to about 5.

5. The metal-containing photoresist developer composition as claimed in claim 1, wherein the developer composition comprises:
50 to 99.99 wt % of the organic solvent; and
0.01 to 50 wt % of the sulfonimide-based compound.

6. The metal-containing photoresist developer composition as claimed in claim 1,
wherein the metal-containing photoresist developer composition is for developing a metal-containing photoresist, and
wherein a metal compound comprised in the metal-containing photoresist is at least one selected from among an organooxy group-containing tin compound and an organocarbonyloxy group-containing tin compound.

7. The metal-containing photoresist developer composition as claimed in claim 1, wherein
wherein the metal-containing photoresist developer composition is for developing a metal-containing photoresist,
wherein the metal-containing photoresist comprises a metal compound represented by Chemical Formula 3 or a condensation thereof: 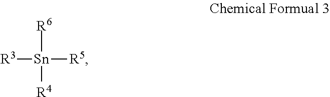
and
wherein, in Chemical Formula 3,
R³ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and -L^{a}-O—R^{a} (wherein L^{a} is a substituted or unsubstituted C1 to C20 alkylene group and R^{a} is a substituted or unsubstituted C1 to C20 alkyl group),
R⁴ to R⁶ are each independently selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, —OR^{b} and —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
at least one selected from among R⁴ to R⁶ are each independently selected from —OR^{b} and —OC(═O)R^{c}.

8. A method of forming patterns, the method comprising:
coating a metal-containing resist composition on a substrate;
coating a composition for removing edge beads from a metal-containing resist along an edge of the substrate;
drying and heating the resultant to form a metal-containing resist layer on the substrate;
exposing the metal-containing resist layer; and
coating the metal-containing photoresist developer composition as claimed in claim 1 and developing the metal-containing photoresist developer composition.
